(19) United States
(12) Patent Application Publication
(10) Pub. No.: US 2015/0059818 A1
(43) Pub. Date: Mar. 5, 2015

(54) METHOD OF PRODUCING FILM OF SURFACE Nb-CONTAINING La-STO CUBIC CRYSTAL PARTICLES

(71) Applicant: National University Corporation Nagoya University, Nagoya-shi (JP)

(72) Inventors: Kunihito KOUMOTO, Nagoya-shi (JP); Feng DANG, Jinan-shi (CN); Nam-Hee PARK, Nagoya-shi (JP); Chunlei WAN, Nagoya-shi (JP); Kazuki TSURUTA, Nagoya-shi (JP)

(21) Appl. No.: 14/202,250

(22) Filed: Mar. 10, 2014

(30) Foreign Application Priority Data
Aug. 29, 2013 (JP) 2013-178408

(51) Int. Cl. H01L 35/22; C30B 19/12; H01L 35/34; C30B 29/32; C30B 29/68; C30B 7/10; C30B 33/06

(52) U.S. Cl. CPC H01L 35/22; C30B 7/10; C30B 19/12; C30B 33/06; C30B 29/32; C30B 29/68; H01L 35/34
USPC 136/200; 117/1; 252/62.3 T

(57) ABSTRACT

There are provided a film of surface Nb-containing La-STO cubic crystal particles that is effective as, for example, a thermoelectric conversion material for use at low temperatures of around room temperature, and an art for producing this film. The production method includes preparing a mixed aqueous solution in which an La-containing compound, an Sr-containing compound, a six-fold coordinated Ti complex compound, and an amphiphilic compound are dissolved; growing cubic-form crystals formed of La-doped STO in the mixed aqueous solution by a hydrothermal synthesis method; obtaining surface Nb-containing La-STO cubic crystal particles by dissolving a niobium-containing compound in this mixed solution and heating; and forming a particle film in which the surface Nb-containing La-STO cubic crystal particles are bonded, by disposing the surface Nb-containing La-STO cubic crystal particles on a substrate and carrying out firing.

### BACKGROUND OF THE INVENTION

1. Field of the Invention

The present invention relates to cubic-form strontium titanate crystals that contain niobium on the surface, to a film containing these crystals, and to a method of producing this film.

The present application cites priority based on Japanese Patent Application 2013-178408 filed Aug. 29, 2013, the contents of which are incorporated in their entirety in this Description by reference.

2. Description of the Related Art

It has been reported that approximately 60% or more of the energy consumed in Japan has in recent years been released into the atmosphere as waste heat that has itself gone unutilized. The utilization of this waste heat by its conversion into electrical energy is desirable for realizing energy conservation and for achieving a reduction in environmental load. Much of this waste heat is released in relatively small amounts from, for example, power plants, factories, and automobiles, and a large portion is at low temperatures of not more than 200° C. Thus, a problem here has been the difficulty of utilizing this waste heat using conventional large-scale energy conversion technologies, e.g., using a turbine, to convert the waste heat into electrical energy. As a consequence, the development is anticipated of a thermoelectric generation technology that, in order to effectively utilize these small amounts of low-temperature waste heat, would be able to generate electricity at high conversion efficiencies even at low temperatures.

Intermetallic compounds using bismuth (Bi) and tellurium (Te) (Bi—Te compounds) are known to be materials that exhibit high thermoelectric generating characteristics in the temperature region at and below 200° C. However, Bi and Te are rare metals and it is thus difficult to acquire the starting material in large quantities. Other problems have also been identified, such as their toxicity and low chemical durability.

### SUMMARY OF THE INVENTION

It is known, on the other hand, that complex oxides with a perovskite crystal structure, e.g., strontium titanate (SrTiO₃: STO), can be produced from combinations of abundant and nontoxic starting materials and exhibit thermoelectric conversion characteristics in addition to various other functionalities, e.g., ferroelectricity, superconductivity, electron-oxygen ion mixed conductivity, and catalytic functionalities. As a consequence, various proposals have been made with respect to thermoelectric conversion materials that use STO. For example, Japanese Patent Application Laid-open No. 2012-186230, Japanese Patent Application Laid-open No. 2013-065669, and Japanese Patent 4,998,897 disclose that the dimensionless figure of merit (ZT, also referred to hereafter simply as the “figure of merit”) can be raised by doping STO with an element such as niobium (Nb) to convert it into an n-type semiconductor, and by organizing the microfine structure at the nanometer level.

However, due to its high thermal conductivity, STO has a low energy conversion efficiency, and, for example, while having a relatively high ZT of about 0.37 (STO monocrystal) at high temperatures of around 1000K, it has a low ZT of about 0.08 (STO monocrystal) at low temperatures around room temperature (typically 25° C.). As a result, thermoelectric conversion materials that are mainly STO have not been acceptable as substitutes for Bi—Te compounds, which have a ZT as high as about 0.9 at room temperature.

The present invention was created to solve the existing problems as described above and has as an object the introduction of a film of surface Nb-containing La-STO cubic crystal particles, that would be effective as, for example, a thermoelectric conversion material used at low temperatures around room temperature. A further object is the introduction of a technology for producing this particle film.

The present inventors carried out intensive investigations in order to improve the thermoelectric conversion characteristics of STO. It was discovered through these investigations that an ideal large voltage and low internal resistance as a thermoelectric conversion material could be realized with an artificial superlattice constructed by the thin-film growth, using a thin-film formation process such as pulsed laser deposition, of an insulating STO and a high-density carrier-doped STO in alternation (refer, for example, to Japanese Patent 4,998,897). There were, however, limitations, e.g., anisotropy is seen in a superlattice having a laminar structure; high costs because the thin-film formation process requires special conditions, e.g., a vacuum, and equipment; and limitations on the substrate for forming the film are present. The present inventors therefore broke away completely from the concept of an artificial superlattice comprising the aforementioned laminar structure and conceived of an entirely novel artificial superlattice that solves the problems cited above and achieved the present invention as a result. Thus, the present invention provides a method for producing a film of surface Nb-containing La-STO cubic crystal particles. This production method characteristically includes the following steps.

(1) Preparing a mixed aqueous solution in which a lanthanum (La)-containing compound, a strontium (Sr)-containing compound, a hexacoordinate titanium complex compound, and an amphiphilic compound are dissolved.

(2) Growing cubic-form crystals formed of strontium titanate (STO) doped with lanthanum, from the mixed aqueous solution by a hydrothermal synthesis method (also referred to, inter alia, as a hydrothermal treatment method).

(3) Dissolving a niobium (Nb)-containing compound in the mixed solution containing the aforementioned cubic-form crystal and holding in the temperature range from 150° C. to 300° C. to obtain surface Nb-containing La-STO cubic crystal particles by epitaxially growing an Nb-containing phase on the surface of the cubic-form crystals. (4) Disposing the surface Nb-containing La-STO cubic crystal particles on a substrate by supplying the solution containing the surface Nb-containing La-STO cubic crystal particles onto the substrate and removing a solvent in the solution.

(5) Forming a particle film in which the surface Nb-containing La-STO cubic crystal particles are bonded, by firing the substrate on which the surface Nb-containing La-STO cubic crystal particles are disposed.

Thus, in this production method, La-containing STO crystals (also referred to in the following, inter alia, simply as “La-STO crystals”) with a cubic particle shape are first produced using a hydrothermal synthesis method. This is followed by the formation, on the surface of the La-STO crystal, of an STO layer that contains both Nb and La (also referred to in the following simply as the “Nb,La-STO layer”). This results in the preparation of the surface Nb-containing La-STO cubic crystal particles. In addition, by forming these surface Nb-containing La-STO cubic crystal particles into a film configuration by bringing about their three-dimensional bonding, quantum well structures are constructed at the bonding zones between the cubic crystal particles. In other words, by sandwiching the Nb,La-STO layer, which is present in an ultrathin-film configuration and exhibits semiconductor properties, with La-STO crystals, which are a different type of semiconductor, the electrons in this Nb,La-STO layer are confined and the electron-confining effect of a two-dimensional electron gas (2DEG) is realized.

This quantum well can be formed, for example, between adjacent La-STO crystals by stacking the surface Nb-containing La-STO cubic crystal particles. For example, quantum wells between adjacent La-STO crystals can be formed even when the surface Nb-containing La-STO cubic crystal particles are laid out adjacently accompanied by some amount of misalignment. In addition, for example, quantum wells can be formed on all the sides of the surface Nb-containing La-STO cubic crystal particles, i.e., on six sides. As a consequence, quantum wells may be constructed three-dimensionally, and a film of surface Nb-containing La-STO cubic crystal particles that can three-dimensionally realize a large voltage and low internal resistance is thus provided. The surface Nb-containing La-STO cubic crystal particles that are a structural element of this film of surface Nb-containing La-STO cubic crystal particles can be conveniently prepared in relatively large amounts by a hydrothermal synthesis method. This enables a cost reduction as compared to the production using conventional thin-film formation technology of an artificial superlattice having a laminar structure. In addition, since a hydrothermal synthesis method is used to form the surface Nb-containing La-STO cubic crystal particles that are a structural element of the film, no limitations are imposed with regard to the substrate by conditions such as the composition and crystal structure and a variety of materials can then be used.

A preferred aspect of the herein disclosed production method is characterized by the production of the film by dripping the solution containing the surface Nb-containing La-STO cubic crystal particles onto the substrate and removing the solvent by drying.

Using this method, the generation of, inter alia, microscopic cracks, can be inhibited and the film of surface Nb-containing La-STO cubic crystal particles can also be produced even more conveniently.

A preferred aspect of the herein disclosed production method is characterized by the disposition of the surface Nb-containing La-STO cubic crystal particles on the substrate by immersing a lower end of the substrate in the solution containing the surface Nb-containing La-STO cubic crystal particles and removing the solvent by drying in a reduced-pressure environment.

This method can bring about a very high degree of alignment of the surface Nb-containing La-STO cubic crystal particles and a film of surface Nb-containing La-STO cubic crystal particles can then be produced in which the quantum wells are periodically formed in two or three dimensions.

In another aspect the present invention provides a surface Nb-containing La-STO cubic crystal particle. This surface Nb-containing La-STO cubic crystal particle contains a cubic-form monocrystal phase having an average particle diameter of 1 nm to 100 nm and formed of lanthanum-doped STO, and an Nb-containing phase formed of a lanthanum- and niobium-doped STO. The monocrystal phrase is further characterized in that each of the faces of the cubic form is constituted of a (100) plane and in that the Nb-containing phase is formed as an epitaxial layer on a surface of this monocrystal phase. That is, the Nb-containing phase can be a phase constituted of the aforementioned Nb,La-STO layer.

This construction provides surface Nb-containing La-STO cubic crystal particles that, for example, can be favorably used to produce the above-described film of surface Nb-containing La-STO cubic crystal particles.

In this Specification, the “average particle diameter” is defined as the arithmetic mean value of the equivalent circle diameter measured on at least 10 measurement targets (for example, the surface Nb-containing La-STO cubic crystal particles) selected within a plurality (for example, two or more) of observational fields or observed images acquired using an observation means such as an electron microscope.

The Nb-containing phase is characteristically constituted of 1 to 10 atomic layers in a preferred aspect of the herein disclosed surface Nb-containing La-STO cubic crystal particles.

Since the Nb-containing phase (the Nb,La-STO layer) in the surface Nb-containing La-STO cubic crystal particles is grown epitaxially on the surface of a cubic-form crystal phase, for example, it can be grown with control of its number of layers. Since, as indicated above, the Nb-containing phase is constructed of a very thin layer, when the film of surface Nb-containing La-STO cubic crystal particles is constructed, the internal resistance can be kept down and in addition the electrons can be stably confined in the Nb-containing phase. The Nb-containing phase preferably has a thickness of not more than 4 atomic layers and more preferably not more than two atomic layers; for example, it is 1 atomic layer. By having the total thickness of adjacent Nb-containing phases be preferably not more than about 4 atomic layers and more preferably not more than 3 atomic layers, the Seebeck coefficient then increases linearly in inverse proportion to the width of these quantum wells and it becomes possible to realize a high figure of merit ZT.

In yet another aspect the present invention provides a dispersion of the surface Nb-containing La-STO cubic crystal particles, in which the surface Nb-containing La-STO cubic crystal particles are dispersed in a dispersion medium. By providing the surface Nb-containing La-STO cubic crystal particles in a dispersed state, for example, the film of the surface Nb-containing La-STO cubic crystal particles can be produced even more conveniently.

In yet another aspect, the present invention provides a film of the surface Nb-containing La-STO cubic crystal particles, in which the surface Nb-containing La-STO cubic crystal particles are disposed in a film configuration and are sintered to each other. Here, the surface Nb-containing La-STO cubic crystal particles are more preferably arrayed with adjacent (100) faces at an angle of not more than 25°.

Arraying these surface Nb-containing La-STO cubic crystal particles with the adjacent (100) faces at an angle of not more than 25° can form a fine and dense microstructure in which quantum wells are formed roughly periodically. Such a construction provides a film of surface Nb-containing La-STO cubic crystal particles that has a high figure of merit ZT and is effective as, inter alia, a heat conversion material. In view of this, the present invention provides this thermoelectric conversion material comprising surface Nb-containing La-STO cubic crystal particles.

### BRIEF DESCRIPTION OF THE DRAWINGS

FIG. 1A and FIG. 1B are high-angle annular dark-field scanning transmission electron microscopic (HAADF-STEM) images, each at different magnifications, of surface Nb-containing La-STO cubic crystal particles obtained in the examples;

FIG. 2A is a high-angle annular dark-field scanning transmission electron microscopic (HAADF-STEM) image of a surface Nb-containing La-STO cubic crystal particle obtained in the examples, and FIG. 2B is a graph that shows the results of a line scan based on this image that gives the constituent element concentration;

FIG. 3A and FIG. 3B are each field emission scanning electron microscopic (FE-SEM) images of films of surface Nb-containing La-STO cubic crystal particles that are obtained in the examples;

FIG. 4A is a high-angle annular dark-field scanning transmission electron microscopic (HAADF-STEM) image of a film of surface Nb-containing La-STO cubic crystal particles that is obtained in the examples, while FIG. 4B is a graph that shows the results of a line scan based on this image that gives the Nb concentration;

FIG. 5 is a graph that shows the Seebeck coefficient S and electrical conductivity a for a film of surface Nb-containing La-STO cubic crystal particles that is obtained in the examples; and

FIG. 6 is a graph that shows the results for the calculation of the power factor (S²σ value) for a film of surface Nb-containing La-STO cubic crystal particles that is obtained in the examples.

### DESCRIPTION OF THE PREFERRED EMBODIMENTS

The method of the present invention for producing a film of surface Nb-containing La-STO cubic crystal particles is primarily described in the following, during which the surface Nb-containing La-STO cubic crystal particles (crystal particles), the dispersion of surface Nb-containing La-STO cubic crystal particles, the film of surface Nb-containing La-STO cubic crystal particles, and the thermoelectric conversion material that are provided by the present invention are also described. Matters required for the execution of the present invention but not particularly described in this Specification (for example, general items related to the production of crystal particles by hydrothermal synthesis) can be understood as design matters for the individual skilled in the art based on the conventional art in the pertinent field. The present invention can be implemented based on the contents disclosed in this Specification and the figures and the common general technical knowledge in the pertinent field.

The method provided by the present invention for producing a film of surface Nb-containing La-STO cubic crystal particles comprises, as described above, steps (1) to (5). Each of these steps is described below.

### [1. Preparation of the Mixed Aqueous Solution]

The mixed aqueous solution used to produce the surface Nb-containing La-STO cubic crystal particles is prepared first. This mixed aqueous solution contains an La-containing compound, an Sr-containing compound, and a six-fold coordinated titanium complex compound, which are starting materials for the surface Nb-containing La-STO cubic crystal particles, in an aqueous solvent (also referred to as a water-based solvent) and additionally contains an amphiphilic compound. These can be understood as the starting materials for the production of La-STO cubic crystal particles by hydrothermal synthesis, and, for example, the preparation can be carried out with reference to the art described in Japanese Patent Application Laid-open No. 2011-068500.

There are no particular limitations on the La-containing compound and the Sr-containing compound other than that they are an La- or Sr-containing compound, and a variety of compounds can be used. Compounds that exhibit solubility in water are preferred. Specific examples are the hydroxides, halides, e.g., chlorides and bromides, nitrates, acetates, alkoxides, formates, and sulfates of La and Sr. More specifically, the La-containing compound can be exemplified by lanthanum hydroxide, lanthanum nitrate hexahydrate, lanthanum chloride heptahydrate, lanthanum bromide, lanthanum acetate hydrate, lanthanum methoxide, lanthanum ethoxide, lanthanum isopropoxide, lanthanum di(methoxyethoxide), lanthanum oxalate nonahydrate, and lanthanum sulfate. The Sr-containing compound can be more specifically exemplified by strontium hydroxide, strontium nitrate, strontium chloride, strontium bromide, strontium acetate, strontium di(methoxyethoxide), strontium dipivaloylmethanoate, strontium formate, strontium oxalate, and strontium sulfate.

Among the preceding, the use of lanthanum hydroxide and strontium hydroxide is preferred.

Various complex compounds in which six-fold coordinated titanium is the central metal can be considered for the six-fold coordinated titanium complex compound. Examples here are complexes in which six-fold coordinated titanium is the central metal and this central metal is stabilized by a chelating agent such as ethylenediaminetetraacetic acid (EDTA), nitrilotriacetic acid (NTA), 2,2′-bipyridyl (bpy), and diethylenetriaminetetraacetic acid (DTPA); a hydroxycarboxylic acid such as citric acid, lactic acid, tartaric acid, malic acid, hydracrylic acid, and glyceric acid; a carboxylic acid such as succinic acid, oxalic acid, maleic acid, malonic acid, acrylic acid, propionic acid, and acetic acid; or an amino acid such as glycine, alanine, serine, glutamic acid, aspartic acid, and cysteic acid. These titanium complex compounds can be exemplified by titanium complexes such as complexes in which, e.g., a carboxylic acid, amino acid, chelating agent, and so forth, is coordinated, and by the ammonium salts of these titanium complexes, e.g., ammonium cysteatoperoxotitanate. More specifically, water-soluble titanium metal complexes are a favorable example, e.g., citratoperoxotitanium complexes.

The La-containing compound, Sr-containing compound, and six-fold coordinated titanium complex compound that are the starting materials as described above may be blended in a stoichiometric ratio that will provide the La-STO crystal particle with the desired composition. For example, production can be carried out to provide the composition with the general formula (Laₓ,Sr₁₋ₓ)TiO₃ where 0<x<1. For example, x, which represents the La doping level, is preferably made about 0.02≦x≦0.5. In addition, insofar as there is no deviation from the objects of the present invention, La-STO cubic crystals may also be prepared in which an element other than La is doped in the STO. In such a case, a compound containing the element to be doped may be added in a stoichiometric ratio as a starting material to the mixed aqueous solution.

The La-STO crystals will be obtained in low yields when these starting materials are present in the aqueous solution in overly small amounts, making this unfavorable. While not intended as a particular limitation, in a preferred example each of these compounds is therefore present in a concentration of at least about 0.01 mmol/L (mol/L is indicated as “M” in the following) and is preferably present in a concentration of at least about 0.1 mM or at least about 1 mM. The production of impurities is prone to occur when the amount in the aqueous solution is too large, making this unfavorable. As a consequence, while not intended as a particular limitation, in a preferred example each of these compounds is present in a concentration of not more than about 1 M and preferably in a concentration of not more than about 100 mM.

Any known compound that has a hydrophilic group and a hydrophobic group in its molecular structure can be used as the amphiphilic compound without particular limitation. Examples are compounds that form an anion upon dissociation in water, e.g., alkylcarboxylic acids, alkylsulfonic acids, and alkyl phosphate compounds; compounds that form a cation upon dissociation in water, e.g., alkylammonium compounds; and polymeric compounds that do not dissociate in water, e.g., polyethylene glycol and polyvinyl alcohol. Viewed from the standpoint of safety for the environment and ease of acquisition, the use is preferred among the preceding of compounds that form an anion upon dissociation in water, e.g., alkylcarboxylic acids, alkylsulfonic acids, and alkyl phosphate compounds. The use of an alkylcarboxylic acid is more preferred.

This alkylcarboxylic acid can be exemplified by saturated fatty acids, e.g., propionic acid, butyric acid, valeric acid, caproic acid, caprylic acid, capric acid, lauric acid, myristic acid, palmitic acid, stearic acid, arachidic acid, behenic acid, and lignoceric acid, and by unsaturated fatty acids such as α-linolenic acid, stearidonic acid, eicosapentaenoic acid, docosahexaenoic acid, linoleic acid, γ-linolenic acid, dihomo-γ-linolenic acid, arachidonic acid, oleic acid, elaidic acid, erucic acid, and nervonic acid. Preferred for use among the preceding are caproic acid, caprylic acid, capric acid, lauric acid, myristic acid, palmitic acid, and stearic acid, which are saturated fatty acids having a C₆₋₂₀ hydrocarbon chain, and oleic acid, linoleic acid, linolenic acid, arachidonic acid, and eicosapentaenoic acid, which are unsaturated fatty acids having a C₆₋₂₀ hydrocarbon chain. The use of oleic acid is particularly preferred in the herein disclosed production method.

The amount of addition of the amphiphilic compound is not particularly limited and can be established as appropriate in conformity to the compound being sought. At a small amount of addition, the average particle diameter of the obtained La-STO crystals may be too large; conversely, at an overly large amount of addition, the desired La-STO crystals may not be obtained. As a consequence, generally a molar amount is preferred that is 0.01 to 100 times the total molar amount of the La-containing compound, Sr-containing compound, six-fold coordinated titanium complex compound, and so forth that are the starting materials. A molar amount that is 0.1 to 10 times is more preferred.

Any solvent that is an aqueous solvent may be used without particular limitation in the mixed aqueous solution. For example, water, e.g., ion-exchanged water, distilled water, pure water, and so forth, can typically be favorably used. Another solvent may be added to this water within a range in which the effects of the present invention are not impaired. There are no particular limitations on this solvent, and it can be exemplified by various hydrocarbons, halogenated hydrocarbons, alcohols, phenols, ethers, acetals, ketones, and esters. Among the preceding, water-soluble organic solvents, e.g., methanol, ethanol, isopropyl alcohol, acetone, methyl ethyl ketone, and so forth, are preferably used. This water-soluble organic solvent can be present at no more than 10 volume % and preferably no more than 3 volume % with reference to the water that is the principle solvent.

The pH of the mixed aqueous solution supplied to the hydrothermal synthesis, infra, is preferably adjusted to 7.5 to 14. The crystal form of the La-STO crystals can be controlled to a more pristine cubic form by controlling the pH into the indicated range. Control of the pH can be realized, for example, by the addition of a basic compound to the mixed aqueous solution. Any basic compound that dissociates in an aqueous solution to exhibit alkalinity can be used without particular limitation as this basic compound. For example, a water-soluble alkali metal compound, e.g., sodium hydroxide, a quaternary ammonium compound, an amine compound, ammonia, pyridine and its derivatives, and hydrazine and its derivatives can be used. Among the preceding, a basic compound free of metal impurities is preferably present, and, for example, the co-use of a metal element-containing basic compound and a metal element-free basic compound is preferred. The metal element-free basic compound can be specifically exemplified by hydrazine; hydrazine derivatives, e.g., 1-monomethylhydrazine, 1,1-dimethylhydrazine, and 1-ethyl-2-methylhydrazine; primary amines such as methylamine, ethylamine, n-propylamine, and ethanolamine; secondary amines such as dimethylamine and diethylamine; and tertiary amines such as trimethylamine and triethylamine. Among the preceding, the use of hydrazine or a derivative thereof is preferred, and the use of hydrazine is even more preferred. For example, the form of the obtained La-STO crystals can be brought even closer to a strict cubic geometry by using at least hydrazine or a derivative thereof as the basic compound, which is thus preferred. The content of the metal element-free basic compound can be adjusted as appropriate in conformity with the pH of the mixed aqueous solution, but, for example, can be from about 1 μM to 12 M as a rough guide. The specific adjustment of the pH can be conveniently carried out by the addition as appropriate of a metal element-containing basic compound.

### [2. Formation of the La-STO Crystals]

Cubic-form crystals (La-STO crystals) comprising lanthanum-doped strontium titanate (STO) are then grown by a hydrothermal synthesis method from the mixed aqueous solution prepared as described above. Specifically, for example, this mixed aqueous solution is held for about 0.5 hours to 24 hours at from room temperature (25° C.) to 300° C. and more preferably 50° C. to 200° C. This step of forming the La-STO crystals can be regarded as the first step in hydrothermal synthesis.

Here, roughly two procedures can be contemplated for growing the La-STO crystals in correspondence to, for example, the properties of the starting materials. In a first procedure, a heat-generating substance is used in the mixed aqueous solution. In this case, La-STO crystal growth is suitably carried out by holding the mixed aqueous solution for about 20 minutes to 40 minutes at a temperature of about 70° C. to 90° C. Holding for around 30 minutes at a temperature of about 80° C. is more preferred. In a second procedure, substances not accompanied by heat generation are used in the mixed aqueous solution. In this case, La-STO crystal growth is suitably carried out by holding the mixed aqueous solution for about 10 hours to 24 hours at a temperature of about 180° C. to 220° C. Holding for about 12 hours to 24 hours at a temperature of about 200° C. is more preferred. The crystal quality declines in either of these procedures when the reaction temperature is too low, which is thus unfavorable. The obtained crystals coarsen and it becomes difficult to control the particle shape when the reaction temperature is too high, which is thus again unfavorable. Growth of the target crystals may be inadequate or may not be obtained at all when the reaction time is too short, which is thus unfavorable. The production efficiency may be reduced and the obtained crystals may undergo coarsening when the reaction time is too long, which is thus again unfavorable.

Cubic-form La-STO crystals (crystal particles) comprising lanthanum-doped strontium titanate (STO) can be obtained by carrying out the preceding. These La-STO crystals have a structure in which La is substituted (doped) into the Sr sites of cubic SrTiO₃ having a perovskite structure, and specifically comprise a lanthanum-doped STO single phase. In addition, the six sides of the cubic form are constructed basically of (100) planes. The particle-to-particle aggregation of these La-STO crystals is inhibited due to the modification of the crystal surface by the amphiphilic compound. These La-STO crystals have an average particle diameter of about 1 nm to 100 nm and can be formed with a relatively narrow particle size distribution (that is, in a state approaching monodispersity). This average particle diameter can be adjusted, for example, using the La doping level, reaction temperature, reaction time, and so forth. In addition, La-STO crystals with a uniform particle size and a shape more nearly approaching a strict cubic geometry can be prepared when the hydrothermal synthesis is carried out in the presence of an amphiphilic compound and a basic compound as has been described above. Preparation of the La-STO crystals by hydrothermal synthesis as described above is preferred because, for example, its execution in a heat- and pressure-resistant vessel, e.g., an autoclave, or in a thermostat enables convenient control of the reaction conditions.

### [3. Formation of the Surface Nb-Containing La-STO Cubic Crystal Particles]

The formation of the La-STO crystals by hydrothermal synthesis is followed by dissolution of a niobium (Nb)-containing compound in the mixed solution containing the La-STO crystals and holding in the temperature range from 150° C. to 300° C. By doing this, an Nb-containing La-STO crystal phase (also referred to herebelow simply as the Nb-containing phase) is grown epitaxially in a layer configuration on the surface of the cubic-form La-STO crystals to thereby obtain surface Nb-containing La-STO cubic crystal particles. This also supports an increase in the crystallinity of the La-STO crystals and a further refinement of the cubic form. In association with the addition of the Nb-containing compound, the mixed solution containing the La-STO crystals may also be cooled to, for example, around room temperature, although this is not required. The step of forming these surface Nb-containing La-STO cubic crystal particles may be considered to be the second step in the hydrothermal synthesis.

A variety of Nb-containing compounds can be used without particular limitation as the Nb-containing compound. A compound that exhibits solubility in water is preferred. Specific examples are the hydroxides, halides, e.g., chlorides and bromides, nitrates, acetates, alkoxides, formates, and sulfates of Nb. More specific examples are niobium hydroxide, niobium chloride, niobium bromide, niobium formate, niobium nitrate, and niobium sulfate and organic salts and organic complexes such as niobium oxalate, ammonium niobium oxalate, niobium lactate, ammonium niobium lactate, niobium alkoxide, pentakis(2-hydroxy-2-oxoacetic acid)niobium salt, sodium niobate, potassium niobate, lithium niobate, and ammonium niobate. This Nb-containing compound is favorably dissolved in an aqueous solvent and in this form added to the mixing vessel. For example, the Nb-containing compound is preferably added as the aqueous solution prepared by dissolution in water or in a mixed solvent of an alcohol and water. The alcohol is favorably a C₁₋₆ lower alcohol such as n-butanol, isopropanol, amyl alcohol, or hexanol. The concentration of the Nb-containing compound in this aqueous solution is not particularly limited, but adjustment to a concentration of about 1 to 10 mM is suitable. In addition, this Nb-containing compound is preferably added so as to provide a proportion of about 0.1 mol % to 5 mol % and preferably about 3 mol % to 4 mol % with respect to the Ti present in the mixed solution.

With regard to the reaction temperature, the crystallinity of the Nb-containing phase is reduced when the temperature in this reaction is too low, which is thus unfavorable. Due to this, for example, the reaction temperature is preferably at least about 150° C. and, for example, is more preferably at least about 170° C. A temperature higher than the reaction temperature in the previously described first step is more preferred. The resulting Nb-containing phase will be thick and/or epitaxial growth may be inhibited when this reaction temperature is too high, which is thus unfavorable. The reaction temperature, for example, is preferably not more than about 280° C. and more preferably is not more than about 250° C. For example, about 200° C. to 220° C. is favorable. A thinner Nb-containing phase is preferred from the standpoint of the thermoelectric conversion characteristics. In addition, the Nb-containing phase is grown epitaxially on the surface of the La-STO crystal (typically a (100) plane). As a consequence, a judicious execution over an adequate period of time is preferred for the reaction time. Viewed from this standpoint, the reaction time is preferably about 12 hours to 60 hours and more preferably about 20 hours to 54 hours, for example, about 24 hours to 36 hours.

The surface Nb-containing La-STO cubic crystal particles obtained as described in the preceding comprise, as described above, a cubic-form monocrystal (La-STO crystal) phase constituted of La-doped STO and an Nb-containing phase constituted of La- and Nb-doped STO. The Nb-containing phase here is formed epitaxially on the surface of the La-STO crystal phase. More preferably, the La-STO crystal phase is a monocrystal phase constituted of a single crystal; each side of the cubic-form La-STO crystal is constituted of a (100) plane; and the Nb-containing phase is formed epitaxially in a layer configuration on the surface of this monocrystal phase. By doing this, a surface Nb-containing La-STO cubic crystal particle is realized that itself has a very low internal resistance.

The thickness of the Nb-containing phase here is not particularly limited, but, for example, can be about 1 to 100 atomic layers. When a film of the surface Nb-containing La-STO cubic crystal particles is formed as described below, a thinner Nb-containing layer is preferred for favorably obtaining a quantum well effect; for example, not more than 50 atomic layers is preferred and not more than 10 atomic layers is more preferred. In particular, the Nb-containing phase preferably has a thickness of not more than 4 atomic layers because the Seebeck coefficient then undergoes a linear increase in inverse proportion to the width of the quantum well and this makes possible the realization of a high figure of merit ZT. Viewed from this perspective, the Nb-containing phase is more preferably not more than 2 atomic layers and, for example, is desirably 1 atomic layer. That is, based on the morphology of the La-STO crystal, this surface Nb-containing La-STO cubic crystal particle can be obtained in the form of surface Nb-containing La-STO cubic crystal particles that have an average particle diameter generally from about several nanometers to several hundred nanometers, for example, about 5 nm to 200 nm, and a relatively narrow particle diameter distribution (i.e., a state approaching monodispersity).

The surface Nb-containing La-STO cubic crystal particles, because they have an amphiphilic compound adsorbed to the surface, can be obtained as a dispersion in which they are dispersed with a good dispersity from each other in the mixed aqueous solution that uses an aqueous solvent. In addition, they can also exist at a good dispersity in nonaqueous solvents due to the adsorption of the amphiphilic compound to the surface of the surface Nb-containing La-STO cubic crystal particles. Accordingly, for example, these surface Nb-containing La-STO cubic crystal particles can be dispersed in a desired solvent using liquid-phase extraction technology. As an example, a nonaqueous solvent, e.g., toluene, can be added to the mixed aqueous solution that contains the surface Nb-containing La-STO cubic crystal particles and centrifugal separation can be carried out to extract the surface Nb-containing La-STO cubic crystal particles into the nonaqueous solvent. As a consequence, a dispersion of the surface Nb-containing La-STO cubic crystal particles dispersed in a freely selected solvent can be provided.

### [4. Disposition of the Surface Nb-Containing La-STO Cubic Crystal Particles on a Substrate]

The surface Nb-containing La-STO cubic crystal particles are then disposed on a substrate by supplying the solution (as desired, this can be a dispersion as described above) containing the surface Nb-containing La-STO cubic crystal particles onto the substrate and removing the solvent in the solution.

There are no particular limitations on the method for supplying the solution containing the surface Nb-containing La-STO cubic crystal particles onto the substrate or on the method for removing the solvent, and various known methods can be used here. The two methods described below can be provided as preferred embodiments for the herein disclosed production method. With regard to the substrate, there are no particular limitations on the composition of its constituent materials, or on its crystal structure, and so forth, and a substrate can be used that has a freely selected composition, crystal structure, and so forth.

(A) the Dripping Method

Here, supply is carried out by directly dripping the solution containing the surface Nb-containing La-STO cubic crystal particles onto the substrate. There are no particular limitations on the removal of the solvent, and, for example, a method can be used in which the solvent is evaporated by spontaneous drying, or a method can be used in which evaporation of the solvent is accelerated, e.g., by exposure to heat, optionally an electron beam or ultraviolet radiation, infrared radiation, and so forth. When an organic material is adsorbed to the surface of the surface Nb-containing La-STO cubic crystal particles, exposure to ultraviolet radiation has the effect of degrading this organic material and thus is preferred. Implementation of the preceding makes it possible to dispose the surface Nb-containing La-STO cubic crystal particles in an aggregated state on the substrate. The thickness at which the surface Nb-containing La-STO cubic crystal particles are disposed in the direction perpendicular to the substrate can be freely controlled by adjusting, for example, the state of the surface of the substrate, the amount of solution dripped thereon, and the number of times the solution dripping procedure is carried out. As an example, the surface Nb-containing La-STO cubic crystal particles can be disposed in a film configuration with a thickness of about 200 nm to 500 nm by carrying out a single dripping procedure. Specifically, the surface Nb-containing La-STO cubic crystal particles can be aggregated and disposed three-dimensionally.

(B) the Vacuum Drying Method

Here, a lower end of the substrate is first immersed in the solution containing the surface Nb-containing La-STO cubic crystal particles and while in this state the substrate and solution are placed in a reduced-pressure environment. By doing this, due to surface tension and osmotic effects the solution ascends from the lower end of the substrate toward its upper end while following the surface of the substrate. At the same time, the surface Nb-containing La-STO cubic crystal particles present in the solution are also carried up the surface of the substrate and are thereby disposed on the substrate. Since an excess of the solvent is not supplied to the substrate, the solvent on the substrate can be easily removed in the reduced-pressure environment. By doing this, the surface Nb-containing La-STO cubic crystal particles can be disposed on the substrate in a compactly aggregated state. The thickness over which the surface Nb-containing La-STO cubic crystal particles are disposed in the direction perpendicular to the substrate cannot be categorically prescribed because it also depends, for example, on the interactions, e.g., surface tension and permeability, between the substrate and the solution and on the time for which the substrate is immersed in the solution. However, as an example, the surface Nb-containing La-STO cubic crystal particles can be disposed in a film configuration having a thickness of about 500 nm to several micrometers (for example, approximately 1 μm). That is, the surface Nb-containing La-STO cubic crystal particles can be disposed arrayed three-dimensionally.

[5. Formation of the Film of Surface Nb-Containing La-STO Cubic Crystal Particles]

A particle film in which the surface Nb-containing La-STO cubic crystal particles are bonded on the substrate can be formed by firing the substrate and the surface Nb-containing La-STO cubic crystal particles that have been disposed on the substrate as described above. The firing conditions can be exemplified by holding at a temperature that enables the surface Nb-containing La-STO cubic crystal particles to undergo sintering. A specific example in this regard is holding for from several minutes to several hours in an inert atmosphere or reducing atmosphere in the temperature range from about 800° C. to 1200° C. Firing can be carried out, for example, in a rare gas atmosphere of, e.g., neon (Ne), argon (Ar), krypton (Kr), and so forth, or in a reducing atmosphere of, e.g., nitrogen (N₂), hydrogen (H₂), and so forth. When such a firing is carried out, the crystals can be bonded to each other by sintering without inducing growth of the surface Nb-containing La-STO cubic crystal particles.

The thusly obtained film of surface Nb-containing La-STO cubic crystal particles has an (La-STO crystal)-(Nb-containing La-STO crystal layer)-(La-STO crystal) structure formed between adjacent surface Nb-containing La-STO cubic crystal particles. That is, a high-density carrier-doped STO crystal layer with a thin-film configuration is sandwiched by La-STO crystals, thereby forming a quantum well. This quantum well can be formed at any periphery of the cubic-form La-STO cubic crystal particle. Thus, for example, a quantum well can be formed on all six sides of the surface of the La-STO cubic crystal particle. As a consequence, a film of surface Nb-containing La-STO cubic crystal particles is provided, in which quantum wells are formed in three dimensions and preferably periodically in three dimensions.

Because the average particle diameter of the surface Nb-containing La-STO cubic crystal particles can generally be approximately 1 nm to 100 nm, this film of surface Nb-containing La-STO cubic crystal particles can form a three-dimensional nanoheterostructure. As a consequence, a film of surface Nb-containing La-STO cubic crystal particles is provided that is a novel STO-based material with improved thermoelectric conversion characteristics. The realization of, for example, a high value of about 0.8 to 1 at 300 K can be anticipated for the figure of merit ZT for this film of surface Nb-containing La-STO cubic crystal particles.

The present invention is specifically described below through examples, but the present invention is not limited by these examples.

Lanthanum hydroxide (La(OH)₃) as the lanthanum source, strontium hydroxide octahydrate (Sr(OH)₂˜8H₂O) as the strontium source, and titanium bis(ammonium lactate) dihydroxide (TALH) as the titanium source were dissolved in 24 mL ion-exchanged water in a tetrafluoroethylene vessel to provide an Sr:Ti:La molar ratio of 1:1:0.05. This mixed aqueous solution was then gelled by the addition to this solution of 6 mL 5 M sodium hydroxide (NaOH). At this time, the Ti concentration in the mixed aqueous solution was adjusted to 0.05 M. After this, hydrazine monohydrate and oleic acid were added in this sequence as amphiphilic compounds to provide a Ti:hydrazine:oleic acid molar ratio of 1:4:8.

The vessel containing this mixed solution was first heated for ten hours in a thermostat at 200° C. (first step); heating of the thermostat was temporarily halted and spontaneous cooling for about one hour was allowed to occur; and niobium ethoxide (Nb(OC₂H₅)₅) dissolved in an ethanol solution was added as the niobium source. The niobium source was adjusted to provide a Ti:Nb molar ratio of 1:0.04. After this, a heat treatment was again carried out for 36 hours in the thermostat at 200° C. while stirring the mixed solution (second step).

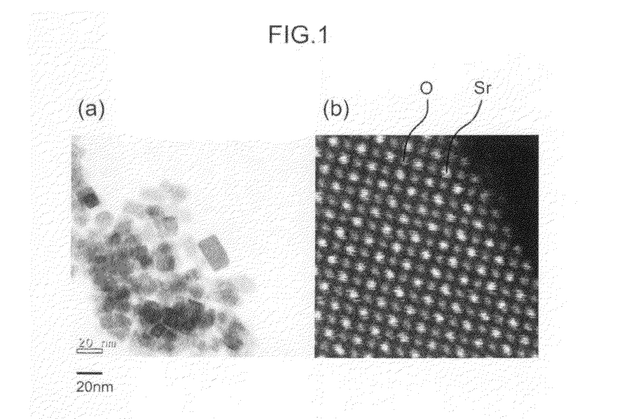

The surface Nb-containing La-STO cubic crystal particles recovered from the mixed solution after the second step were observed with a high-angle annular dark-field scanning transmission electron microscope (HAADF-STEM), and the results are given in FIGS. 1A and 1B. As shown in FIG. 1A, the results confirmed the formation of cubic-form crystal particles having an average particle diameter of 15 to 20 nm. As shown in FIG. 1B, the surface of these crystal particles was confirmed to be constituted of a (100) face.

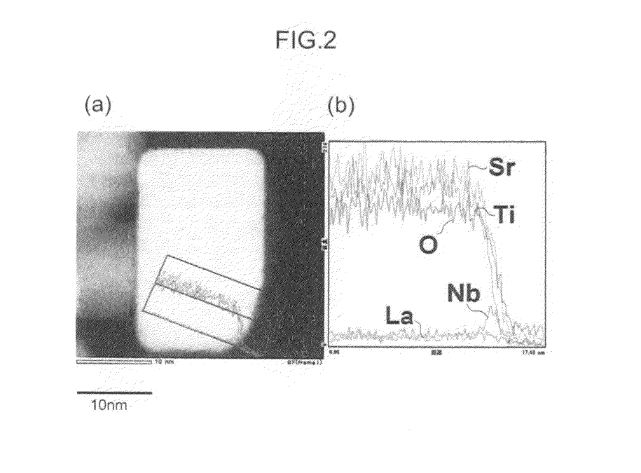

Then, using the surface Nb-containing La-STO cubic crystal particles, the concentration change for each element in a randomly selected line on a sample crystal was checked by an incorporation assay with an energy-dispersive x-ray spectroscopic analyzer (EDS) of the characteristic x-rays generated from each measurement point while scanning (line scan) on the sample with a scanning transmission electron microscope (STEM). These results are given as the concentration change of the individual elements in the STEM image in FIG. 2A and in the line scan in FIG. 2B. It was confirmed that each of the elements Sr, Ti, O, and La were present almost uniformly in the sample crystal and that Nb was present only at end of the scan (i.e., the surface portion of the crystal) of the crystal particle. Based on this, it was confirmed that surface Nb-containing La-STO cubic crystal particles had been obtained in which an Nb- and La-doped Nb,La-STO layer was formed on the surface of the La-STO crystal.

The crystal particles recovered from the mixed solution after the second step were then dispersed in a toluene solution and in this state were dripped onto a silicon substrate; the solvent was dried off under exposure to UV to form a particle film (1) constituted of these crystal particles. In addition, a dispersion was prepared by dispersing the crystal particles recovered from the mixed solution after the second step in a toluene solution; this dispersion and a silicon substrate were placed in a screw-cap vial; and a particle film (2) was formed from the crystal particles by evaporation in a vacuum drier. In performing this vacuum drying, the silicon substrate was tilted at an angle of 60° to 70° to the vial wall of the screw-cap vial with the lower end of the silicon substrate immersed in the dispersion, and this was held at quiescence in the vacuum drier set to 3.2 kPa and 45° C.

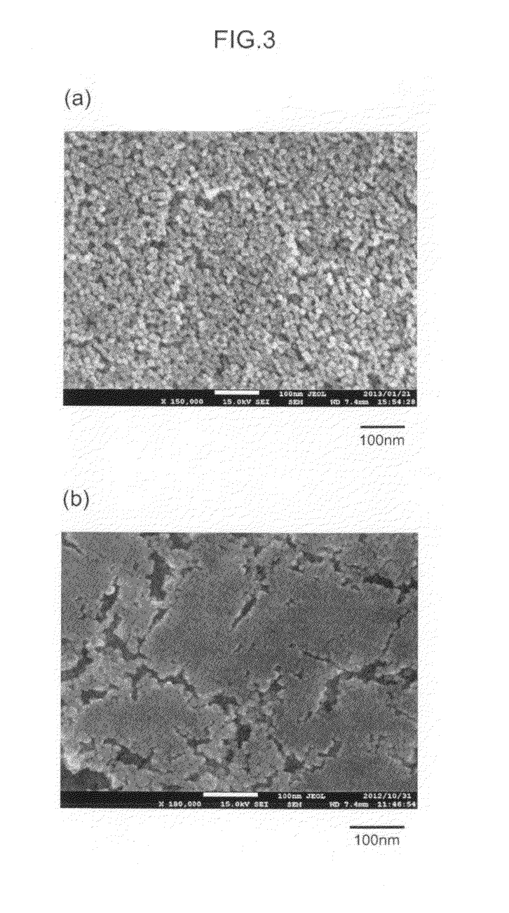

The obtained particle film (1) and particle film (2) were observed with a field emission scanning electron microscope (FE-SEM). The results are given in FIG. 3A and FIG. 3B, respectively. As shown in FIG. 3A, the surface Nb-containing La-STO cubic crystal particles in particle film (1) were observed to form aggregates relatively randomly without alignment while forming gaps. With the particle film (2), on the other hand, the surface Nb-containing La-STO cubic crystal particles were observed to undergo an organized aggregation with a fine and dense alignment, although in very small areas, as shown in FIG. 3B. In addition, when the particle film (2) was subjected to XRD analysis, the surface Nb-containing La-STO cubic crystal particles were observed to be aligned in the [100] direction.

The randomly aggregated surface Nb-containing La-STO cubic crystal particles were sintered by executing a heat treatment in a reducing atmosphere of 40% H₂ at 1000° C. on the particle film (1) obtained as described above. SEM observation of the particle film (1) after this heat treatment confirmed that sintering had occurred while no growth in the surface Nb-containing La-STO cubic crystal particles was seen.

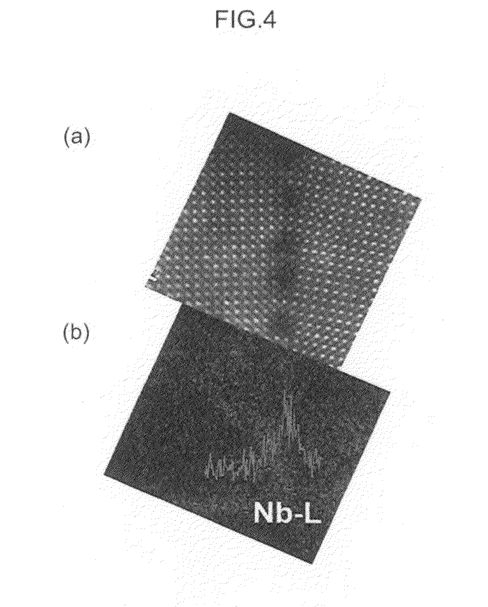

The particle film (1) was also subjected to HAADF-STEM observation and EDS analysis. These results are given as the STEM image in FIG. 4A and the line scan results in FIG. 4B. It could be confirmed from the STEM image of the particle film (1) that, for example, the Sr atoms, seen as white dots in the figure, in the surface Nb-containing La-STO cubic crystal particles were regularly aligned and constituted a (100) plane. In addition, a feature was clearly observed at the interface of two adjacent crystal particles in which the (100) faces of the individual crystals were joined at an angle of about 20°. A state was also observed at this interface in which the Sr atoms and the Ti atoms were approximately correspondingly matched. The results from the line scan confirmed that Nb was present in a local region of this crystal interface at a thickness of about 2 atomic layers each, and the realization of the electron confinement of a two-dimensional electron gas could thus be predicted.

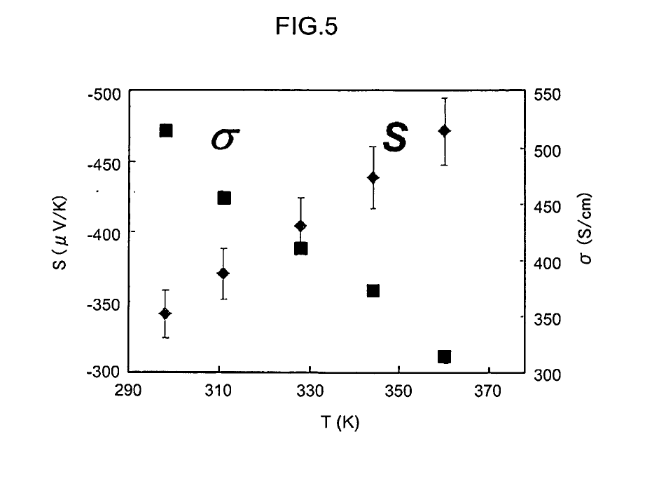

The Seebeck coefficient S and the electrical conductivity a were measured on the particle film (1) at different measurement temperatures from 300 K to 360 K. These results are given in FIG. 5. The Seebeck coefficient was measured based on the direct-current two-contact voltage·temperature measurement method using a Peltier device. The electrical conductivity was measured and calculated based on the direct-current four-contact (van der Pauw) method.

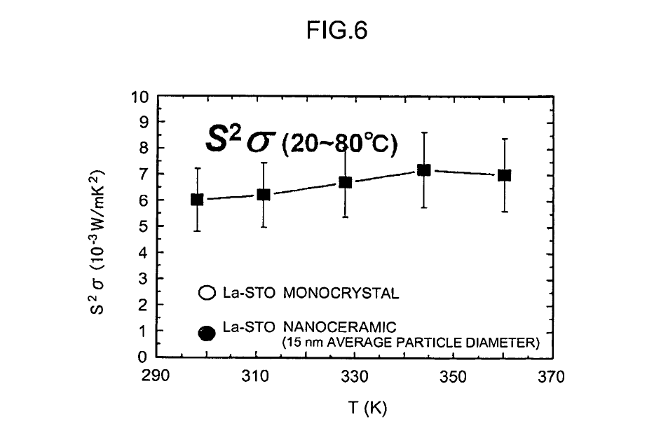

As is clear from FIG. 5, the appearance of n-type degenerate semiconductor properties could be confirmed for particle film (1). The power factor (S²σ) was calculated based on this Seebeck coefficient S and electrical conductivity a and these results are given in FIG. 6. As shown in FIG. 6, particle film (1) was confirmed to have a substantially higher power factor value than lanthanum-doped La-STO monocrystal and a nanoceramic composed of lanthanum-doped La-STO. Based on this, it was shown that the instant film of surface Nb-containing La-STO cubic crystal particles is effective as a thermoelectric conversion material.

The present invention has been described in the preceding based on preferred embodiments, but this description is not limiting and of course various modifications are possible.

1. A method for producing a film of surface Nb-containing La-STO cubic crystal particles, comprising:
preparing a mixed aqueous solution being dissolving a lanthanum-containing compound, a strontium-containing compound, a six-fold coordinated titanium complex compound, and an amphiphilic compound;
growing cubic-form crystals formed of strontium titanate (STO) doped with lanthanum, from the mixed aqueous solution by a hydrothermal synthesis method;
dissolving a niobium-containing compound in the mixed solution containing the cubic-form crystal and holding in the temperature range from 150□C to 300□C to obtain surface Nb-containing La-STO cubic crystal particles by epitaxially growing an Nb-containing phase on a surface of the cubic-form crystals;
supplying the solution containing the surface Nb-containing La-STO cubic crystal particles onto a substrate and removing a solvent from the solution to dispose the surface Nb-containing La-STO cubic crystal particles on the substrate; and
firing the substrate on which the surface Nb-containing La-STO cubic crystal particles are disposed to forming a particle film consisting of the bonded surface Nb-containing La-STO cubic crystal particles.

2. The method for producing a film of surface Nb-containing La-STO cubic crystal particles according to claim 1, wherein the film is produced by dripping the solution containing the surface Nb-containing La-STO cubic crystal particles onto the substrate and removing the solvent by drying.

3. The method for producing a film of surface Nb-containing La-STO cubic crystal particles according to claim 1, wherein the surface Nb-containing La-STO cubic crystal particles are disposed on the substrate by soaking a lower end of the substrate in the solution containing the surface Nb-containing La-STO cubic crystal particles and removing the solvent by drying in a reduced-pressure environment.

4. A surface Nb-containing La-STO cubic crystal particle, comprising:
a monocrystal phase with cubic-form having an average particle diameter of 1 nm to 100 nm and composed of strontium titanate (STO) doped with lanthanum,
each of faces of the monocrystal phase being constituted of a plane; and
an Nb-containing phase composed of strontium titanate (STO) doped with lanthanum and niobium,
the Nb-containing phase epitaxially formed in a layer configuration on a surface of the monocrystal phase.

5. The surface Nb-containing La-STO cubic crystal particle according to claim 4, wherein the Nb-containing phase is constituted of 1 to 10 atomic layers.

6. A film of surface Nb-containing La-STO cubic crystal particles, comprises:
surface Nb-containing La-STO cubic crystal particles, disposed in a film configuration and sintered to each other.

7. The film of surface Nb-containing La-STO cubic crystal particles according to claim 6, wherein adjacent faces of the surface Nb-containing La-STO cubic crystal particles are arrayed at an angle of not more than 25°.
